(19) United States
(12) Patent Application Publication
(10) Pub. No.: US 2025/0230544 A1
(43) Pub. Date: Jul. 17, 2025

(54) DIETHYL ZINC AND METAL HALIDE PRECURSORS FOR DEPOSITION OF METAL FILMS ON SEMICONDUCTOR SUBSTRATES

(71) Applicant: Applied Materials, Inc., Santa Clara, CA (US)

(72) Inventors: Srinivas Gandikota, Santa Clara, CA (US); Yixiong Yang, Fremont, CA (US); Tuerxun Ailihumaer, Santa Clara, CA (US); Geetika Bajaj, Cupertino, CA (US); Seshadri Ganguli, San Jose, CA (US); Vijay Tripathi, Mumbai, Maharashtra (IN); Jayeeta Sen, Mumbai (IN); Gopi Chandran, Mumbai, Maharashtra (IN)

(73) Assignee: Applied Materials, Inc., Santa Clara, CA (US)

(21) Appl. No.: 18/591,976

(22) Filed: Feb. 29, 2024

(30) Foreign Application Priority Data
Jan. 11, 2024 (IN) 202441002179

(51) Int. Cl. C23C 16/455; C23C 16/08; C23C 16/18; H01L 21/285

(52) U.S. Cl. CPC C23C 16/45525; C23C 16/08; C23C 16/18; H01L 21/28556; H01L 21/28568

(57) ABSTRACT

Methods for depositing metal films using a metal halide precursor and diethyl zinc are described. The substrate is exposed to a first metal precursor and diethyl zinc to form the metal film. The exposures can be sequential or simultaneous. The metal films are pure with a low carbon content. The first metal precursor may be a metal halide selected from the group consisting of tantalum chloride, aluminum chloride, niobium chloride, titanium chloride, zirconium chloride, hafnium chloride, tungsten chloride, molybdenum chloride, tantalum bromide, aluminum bromide, niobium bromide titanium bromide, zirconium bromide, hafnium bromide, tungsten bromide, molybdenum bromide, tantalum fluoride, aluminum fluoride, niobium fluoride, titanium fluoride, zirconium fluoride, hafnium fluoride, tungsten fluoride, molybdenum fluoride, tantalum iodide, aluminum iodide, niobium iodide, titanium iodide, zirconium iodide, hafnium iodide, tungsten iodide, and molybdenum iodide.

### CROSS-REFERENCE TO RELATED APPLICATIONS

This application claims priority to Indian Application No. 202441002179, filed Jan. 11, 2024, the entire disclosure of which is hereby incorporated by reference herein.

### TECHNICAL FIELD

Embodiments of the disclosure relate to methods for depositing metal films. More particularly, embodiments of the disclosure are directed to ALD methods which react a halide precursor and diethyl zinc to deposit a metal film on a semiconductor substrate.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

Current metal deposition methods rely on the use of strong reducing agents to react with metal precursors (e.g., metal halides, metal organics) to form pure metal films. These reactions can produce films that contain elevated concentrations of contaminants such as carbon, oxygen, nitrogen, and/or halides that may be deleterious to the target film application.

Accordingly, there is a need for alternative metal deposition methods that provide relatively pure metal films at high growth rates.

### SUMMARY

One or more embodiments of the disclosure are directed to a method of depositing a film on a semiconductor substrate. In one or more embodiments, the method comprises: sequentially exposing a substrate surface to a metal halide precursor comprising a first metal and diethyl zinc to form a metal film comprising the first metal and zinc, wherein the metal film has a carbon concentration of less than or equal to 5 atomic percent.

Additional embodiments of the disclosure are directed to a method of depositing a film on a semiconductor substrate. In one or more embodiments, the method comprises: sequentially exposing at least a portion of a substrate surface to a metal halide precursor and a diethyl zinc to form a metal film without exposing the substrate surface to a strong reductant.

Further embodiments of the disclosure are directed to a method of depositing a metal alloy film on a semiconductor substrate. In one or more embodiments, the method comprises: exposing a substrate surface to a metal halide precursor comprising a first metal to form a reactive species on the substrate surface; and exposing the substrate surface to diethyl zinc to react with the reactive species to form the metal alloy film comprising the first metal and zinc, wherein the metal alloy film has a carbon concentration of less than or equal to 5 atomic percent.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIGS. 2A-2B illustrate cross-sectional views of a substrate being processed in accordance with one or more embodiments;

FIGS. 3A-3B illustrate cross-sectional views of a substrate being processed in accordance with one or more embodiments; and

FIGS. 4A-4B illustrate cross-sectional views of a substrate being processed in accordance with one or more embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Embodiments of the disclosure provide deposition of metal films using reactions between metal halide precursors and diethyl zinc (DEZ). The process of various embodiments uses vapor deposition techniques, such as an atomic layer deposition (ALD) or chemical vapor deposition (CVD) to provide metal and/or metal alloy films. The method of one or more embodiments advantageously does not require the use of a strong reducing agent (e.g., direct plasmas, hydrogen gas at high temperature >600° C.) to form the pure metal film. The method of one or more embodiments uses the reaction between diethyl zinc and a metal halide precursor to effectively grow/form a pure metal film.

One or more embodiment of the disclosure advantageously provides metal films which are relatively pure and/or deposited at relatively low temperatures (e.g., <500° C.). Additionally, one or more embodiments provide metal films which have a relatively low carbon content. Further embodiments of the disclosure advantageously provide methods which do not use strong reducing agents.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

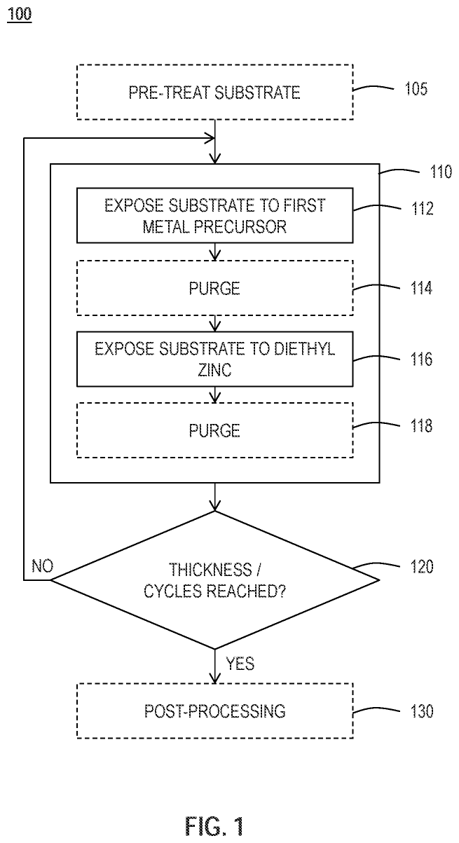

With reference to FIG. 1, one or more embodiments of the disclosure are directed to method 100 of depositing a metal film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In one or more embodiments, the method comprises a chemical vapor deposition (CVD) process in which the reactive gases are mixed in the processing chamber to allow gas phase reactions of the reactive gases and deposition of the thin film.

In one or more embodiments, the method 100 includes a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 105. In other embodiments, metal deposition can be performed without the need for an adhesion liner.

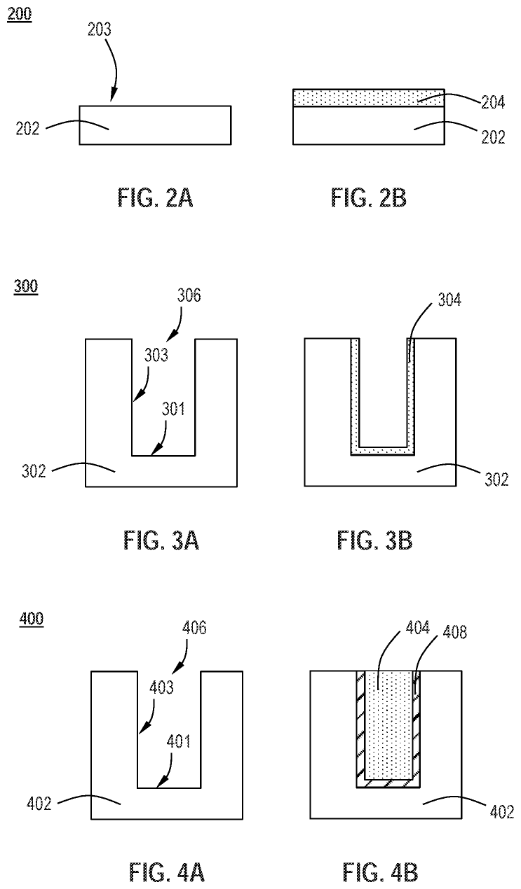

At deposition 110, a process is performed to deposit a metal film on the substrate (or substrate surface). As illustrated in FIGS. 2A to 2B, which illustrate cross-sectional views of a substrate 202 being processed according to the method 100, a metal film 204 is deposited on a substrate 202 having at least one surface 203. The deposition process can include one or more operations to form the film on the substrate. In operation 112, the substrate (or substrate surface) is exposed to a first metal precursor to form a reactive species on the substrate (or substrate surface). The first metal precursor can be any suitable compound that can react with (i.e., adsorb or chemisorb onto) the substrate surface to leave a metal-containing reactive species on the substrate surface.

In one or more embodiments, the first metal precursor is a metal halide precursor. As used in this regard, a metal halide precursor comprises a metal atom or atoms and a plurality of ligands, the ligands consisting essentially of halide ligands. As used in this regard, a precursor “consisting essentially of halide ligands” has greater than or equal to about 90%, greater than or equal to about 95% or greater than or equal to about 99% halide ligands as a percentage of all ligands.

The first metal precursor comprises a metal. In one or more embodiments, the metal is selected from tantalum (Ta), aluminum (Al), niobium (Nb), titanium (Ti), zirconium (Zr), hafnium (Hf), tungsten (W), and molybdenum (Mo). In one or more embodiments, the metal is tantalum (Ta).

As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F−), chloride (Cl−), bromide (Br−), iodide (I−), and astatide (At−). Accordingly, as used herein, the term “metal halide” refers to any complex of a metal with one or more halogen or halide ligand. The term metal halide includes metal mixed halides which have at least two different halide atoms. Non-limiting examples of metal halide precursors include tantalum chloride (TaₘClₙ), aluminum chloride (AlₘClₙ), niobium chloride (NbₘClₙ), titanium chloride (TiClₙ), zirconium chloride (ZrₘCl₄), hafnium chloride (HfₘCl₄), tungsten chloride (WₘClₙ), molybdenum chloride (MoₘClₙ), tantalum bromide (TaₘBrₙ), aluminum bromide (AlₘBrₙ), niobium bromide (NbₘBrₙ), titanium bromide (TiₘBrₙ), zirconium bromide (ZrₘBrₙ), hafnium bromide (HfₘBrₙ), tungsten bromide (WₘBrₙ), molybdenum bromide (MoₘBrₙ), tantalum fluoride (TaₘFₙ), aluminum fluoride (AlₘFₙ), niobium fluoride (NbₘFₙ), titanium fluoride (TiₘFₙ), zirconium fluoride (ZrₘFₙ), hafnium fluoride (HfₘFₙ), tungsten fluoride (WₘFₙ), molybdenum fluoride (MoₘFₙ), tantalum iodide (TaₘIₙ), aluminum iodide (AlₘIₙ), niobium iodide (NbₘIₙ), titanium iodide (TiₘIₙ), zirconium iodide (ZrₘIₙ), hafnium iodide (HfₘIₙ), tungsten iodide (WₘIₙ), and molybdenum iodide (MoₘI_{y}). As recognized by one of skill in the art, m represents the number of metal atoms (M) in the metal halide (MₘXₙ) and n represent the number of halide atoms in the metal halide. One of skill in the art understands that m and n can be whole numbers or decimal numbers.

At operation 114, the processing chamber is optionally purged to remove unreacted first metal precursor; e.g., metal halide, reaction products and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the first metal precursor by any suitable technique including, but not limited to, moving the substrate through a gas curtain to a portion or sector of the processing chamber that contains none or substantially none of the first metal precursor. In one or more embodiments, purging the processing chamber comprises applying a vacuum. In one or more embodiments, purging the processing chamber comprises flowing a purge gas over the substrate. In one or more embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

At operation 116, the substrate (or substrate surface) is exposed to a second metal precursor to form a metal film on the substrate. The second metal precursor can react with the reactive species on the substrate surface from the first metal precursor, e.g., the metal halide, to form the metal film.

In one or more embodiments, the second metal precursor is a metal organic precursor. As used in this regard, a metal organic precursor comprises a central metal atom or atoms and a plurality of ligands, the ligands consisting essentially of ligands coordinated to the metal atom(s) by carbon or hydrogen. In one or more embodiments, the coordinated ligands are alkyl ligands. In one or more embodiments, the metal organic precursor comprises an alkyl metal hydride. In one or more embodiments, the metal organic precursor comprises a metal hydride. In one or more embodiments, the second metal precursor comprises an alkyl zinc compound. In one or more embodiments, the second metal precursor is diethyl zinc.

Unless otherwise indicated, the term “lower alkyl,” “alkyl,” or “alk” as used herein alone or as part of another group includes both straight and branched chain hydrocarbons, containing 1 to 20 carbons, 1 to 10 carbons, 1 to 6 carbons or 1 to 4 carbons in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

In one or more embodiments, it has been surprisingly found that the reaction of metal halide and diethyl zinc (DEZ) can provide unexpectedly pure metal films. In one or more embodiments, the metal films have low carbon content. Accordingly, in one or more embodiments, a metal film with high purity may be produced by CVD or ALD. In one or more embodiments, the carbon concentration of the metal film is less than or equal to about 10 atomic percent, less than or equal to about 5 atomic percent, less than or equal to about 2 atomic percent, or less than or equal to about 1 atomic percent.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the metal film, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, a silicon oxide (SiOx) substrate, a hafnium oxide (HfOx) substrate, or the like. In one or more embodiments, one or more additional layers may be disposed on the substrate such that the metal film may be at least partially formed thereon. For example, in one or more embodiments, a layer comprising a metal, a nitride, an oxide, or the like, or combinations thereof may be disposed on the substrate and may have the metal film formed upon such layer or layers. In specific embodiments, at least one layer of silicon oxide (SiOx) is disposed on the substrate. The silixon oxide layer(s) may have any suitable thickness, including in a range of from 8 Å to 12 Å. In other embodiments, at least one layer of hafnium oxide (HfOx) is disposed on the substrate. The hafnium oxide layer(s) may have any suitable thickness, including in a range of from 8 Å to 20 Å.

As will be appreciated by one of skill in the art, that, in one or more embodiments, the substrate may be first exposed to the first metal precursor, e.g., metal halide, and then subsequently be exposed to the second metal precursor, e.g., alkyl zinc or diethyl zinc, to form the metal film. In other embodiments, however, the substrate may be first exposed to the second metal precursor, e.g., alkyl zinc or diethyl zinc, and then subsequently be exposed to the first metal precursor, e.g., metal halide, to form the metal film. Regardless, the deposition 110 can be described as exposing the substrate (or substrate surface) to a metal halide and a metal organic precursor or second metal precursor or alkyl zinc or diethyl zinc.

Similar to the first metal precursor, the second metal precursor comprises a second metal selected from tantalum (Ta), aluminum (Al), niobium (Nb), titanium (Ti), zirconium (Zr), hafnium (Hf), tungsten (W), zinc (Zn), and molybdenum (Mo). In one or more embodiments, the metal is tantalum (Zn).

In one or more embodiments, the metal of metal halide and the metal of the metal organic precursor are independently selected. Accordingly, in one or more embodiments, the metal of metal halide and the metal of the metal organic precursor are the same metal and a metal film comprising a single metal is deposited. Alternatively, in one or more embodiments, the metal of metal halide and the metal of the metal organic precursor are different metals and a bimetallic film comprising two metals is deposited. In other embodiments, the metal of the metal halide and the metal of the metal organic precursor are different metals and a metal film comprising substantially only a single metal is deposited. As used in this specification and the appended claims, the term substantially only means that the metal film contains less than about 10 atomic %, including less than about 9%, less than about 8%, less than about 7%, less than about 6%, less than about 5%, including less than about 4%, less than about 3%, less than about 2%, less than about 1%, less than about 0.5%, and less than about 0.1% of the total composition of the metal film is a second metal.

In one or more embodiments, a bimetallic film may also be referred to as a metal alloy film. In one or more embodiments, when the first precursor is a metal halide and the metal organic precursor is an alkyl zinc precursor or diethyl zinc, the metal alloy film comprises one or more of tantalum zinc (TaZn), aluminum zinc (AlZn), niobium zinc (NbZn), titanium zinc (TiZn), zirconium zinc (ZrZn), hafnium zinc (HfZn), tungsten zinc (WZn), and molybdenum zinc (MoZn). In one or more embodiments, the metal or bimetallic film comprises in a range of from 0.5 atomic % to 20 atomic % of zinc (Zn). In other embodiments, the metal film or the bimetallic film contains less than about 10 atomic %, including less than about 9%, less than about 8%, less than about 7%, less than about 6%, less than about 5%, including less than about 4%, less than about 3%, less than about 2%, less than about 1%, less than about 0.5%, and less than about 0.1% of zinc (Zn).

Typical deposition schemes include the reaction of a metal precursor (e.g., a metal halide or metal organic precursor) to a reductant to remove ligands from the metal precursor and electrochemically reduce the oxidation state of the metal atom to form the metal film. In contrast, without being bound by theory, it is believed that the disclosed method 100 relies on the reaction of the metal halide with the diethyl zinc to form the metal film. Accordingly, in one or more embodiments, the metal film is deposited without exposing the substrate (or substrate surface) to a strong reductant. As used in this regard, a strong reductant may comprise hydrogen gas (H₂) and/or any direct plasmas.

At operation 118, the processing chamber is optionally purged after exposure to the second metal precursor. Purging the processing chamber in operation 118 can be the same process or different process than the purge in operation 114. Purging the processing chamber, portion of the processing chamber, area adjacent the substrate surface, etc., removes unreacted reactants, reaction products and by-products from the area adjacent the substrate surface.

While not illustrated in FIG. 1, the deposition 110 may further comprise exposing the substrate (or substrate surface) to an additional reactant to facilitate or expedite deposition of the metal film. In one or more embodiments, the additional reactant comprises one or more of an amine, a silane, deuterium, or a metal hydride. In one or more embodiments, the metal hydride comprises the metal of metal halide or the metal of the metal organic precursor.

At decision 120, the thickness of the deposited film, or number of cycles of the metal halide precursor and the metal organic precursor is considered. If the deposited film has reached a predetermined thickness or a predetermined number of process cycles have been performed, the method 100 moves to an optional post-processing operation 130. If the thickness of the deposited film or the number of process cycles has not reached the predetermined threshold, the method 100 returns to operation 110 to expose the substrate surface to the first metal precursor, e.g., metal halide, again in operation 112, and continuing.

The optional post-processing operation 130 can be, for example, a process to modify film properties (e.g., annealing) or a further film deposition process (e.g., additional ALD or CVD processes) to grow additional films. In one or more embodiments, the optional post-processing operation 130 can be a process that modifies a property of the deposited film. In one or more embodiments, the optional post-processing operation 130 comprises annealing the as-deposited film. In one or more embodiments, annealing the as-deposited film comprises rapid thermal processing (RTP), laser anneal, or spike anneal. In one or more embodiments, annealing is done at temperatures in the range of about 300° C., 400° C., 500° C., 600° C., 700° C., 800° C., 900° C. or 1000° C.

Annealing can be performed for any suitable length of time. In one or more embodiments, the film is annealed for a predetermined time in the range of about 15 seconds to about 90 minutes, or in the range of about 1 minute to about 60 minutes. In one or more embodiments, annealing the as-deposited film increases the density, decreases the resistivity and/or increases the purity of the film. In one or more embodiments, annealing can also with performed with a gas under plasma. In one or more embodiments, the annealing temperature may be lower with plasma.

The annealing environment of one or more embodiments comprises one or more of an inert gas (e.g., molecular nitrogen (N₂), argon (Ar)) or a reducing gas (e.g., molecular hydrogen (H₂), deuterium (D₂), or ammonia (NH₃)).

In one or more embodiments, the plasma comprises one or more of nitrogen (N₂), argon (Ar), helium (He), hydrogen (H₂), carbon monoxide (CO), carbon dioxide (CO₂), methane (CH₄), and ammonia (NH₃). In one or more embodiments, the plasma comprises or consists essentially of one or more of nitrogen radicals or argon radicals or helium radicals or hydrogen radicals or carbon monoxide radicals or carbon dioxide radicals or methane radicals or ammonia radicals. In one or more embodiments, the plasma comprises or consists essentially of nitrogen and hydrogen radicals. In one or more embodiments, the plasma is a remote plasma. In other embodiments, the plasma is a direct plasma.

In one or more embodiments, the plasma may be generated remotely or within the processing chamber. In one or more embodiments, the plasma is an inductively coupled plasma (ICP) or a conductively coupled plasma (CCP). Any suitable power can be used depending on, for example, the reactants, or the other process conditions. In one or more embodiments, the plasma is generated with a plasma power in the range of about 10 W to about 3000 W. In one or more embodiments, the plasma is generated with a plasma power less than or equal to about 3000 W, less than or equal to about 2000 W, less than or equal to about 1000 W, less than or equal to about 500 W, or less than or equal to about 250 W.

The method 100 can be performed at any suitable temperature depending on, for example, the first metal precursor, the second metal precursor or thermal budget of the device. In one or more embodiments, the use of high temperature processing may be undesirable for temperature-sensitive substrates, such as logic devices. In one or more embodiments, exposure to the first metal precursor, e.g., metal halide (operation 112) and the second metal precursor, e.g., diethyl zinc (operation 116) occur at the same temperature. In one or more embodiments, the substrate is maintained at a temperature in a range of about 20° C. to about 400° C., or about 50° C. to about 500° C.

In one or more embodiments, exposure to the first metal precursor, e.g., metal halide (operation 112) occurs at a different temperature than the exposure to the second metal precursor, e.g., diethyl zinc (operation 116). In one or more embodiments, the substrate is maintained at a first temperature in a range of about 20° C. to about 400° C., or about 50° C. to about 650° C., for the exposure to the first metal precursor, and at a second temperature in the range of about 20° C. to about 400° C., or about 50° C. to about 650° C., for exposure the second metal precursor.

In one or more embodiments, exposure of the substrate to different temperatures is facilitated by a multi-station processing platform. In one or more embodiments, the multi-station processing platform performs a spatial ALD process thereby allowing multiple substrates to be processed in different processing stations at different temperatures within the same chamber.

In the embodiment illustrated in FIG. 1, at deposition operation 110 the substrate (or substrate surface) is exposed to the first metal precursor, e.g., metal halide, and the second metal precursor, e.g., diethyl zinc, sequentially. In another, unillustrated, embodiment, the substrate (or substrate surface) is exposed to the first metal precursor, e.g., metal halide, and the second metal precursor, e.g., diethyl zinc, simultaneously in a CVD reaction. In a CVD reaction, the substrate (or substrate surface) can be exposed to a gaseous mixture of the first metal precursor, e.g., metal halide, and the second metal precursor, e.g., diethyl zinc, to deposit a metal film having a predetermined thickness. In the CVD reaction, the metal film can be deposited in one exposure to the mixed reactive gas or can be multiple exposures to the mixed reactive gas with purges between.

In one or more embodiments, the metal film formed by method 100 comprises an elemental metal film. In one or more embodiments, the metal film consists essentially of a single metal. In one or more embodiments, the metal film comprises a bimetallic or alloyed film consisting essentially of the metal of metal halide and the metal of the metal organic precursor. As used in this manner, the term “consists essentially of” means that the metal film is greater than or equal to about 80%, 85%, 90%, 95%, 98%, 99% or 99.5% of the stated metal(s), on an atomic basis. Measurements of the composition of the metal film refer to the bulk portion of the film, excluding interface regions where diffusion of elements from adjacent films or surface oxidation/contamination may occur.

In one or more embodiments, the metal film formed by method 100 has a carbon concentration of less than or equal to about 10 atomic percent, less than or equal to about 5 atomic percent, less than or equal to about 2 atomic percent, less than or equal to about 1 atomic percent, or less than or equal to about 0.5 atomic percent.

The deposition operation 110 can be repeated to form a metal film having a predetermined thickness. In one or more embodiments, the deposition operation 110 is repeated to provide a metal film having a thickness in the range of about 0.05 nm to about 20 nm, or in the range of about 5 Å to about 200 Å.

One or more embodiments of the disclosure are directed to methods of depositing metal films in high aspect ratio features of semiconductor structures such as for the deposition of metal gates, dipoles, gap fill material, and the like. A high aspect ratio feature is a trench, via, or pillar having a height:width ratio greater than or equal to about 10, 20, or 50, or more. In one or more embodiments, the metal film is deposited conformally on the high aspect ratio feature. As used in this manner, a conformal film has a thickness near the top of the feature that is in the range of about 80-120% of the thickness at the bottom of the feature. As illustrated in FIGS. 3A to 3B, which illustrate cross-sectional views of a substrate 302 being processed according to the method 100, a metal film 304 is deposited on a substrate 302 having at least one feature 306 including a bottom 301 and at least on sidewall surface 303. In one or more embodiments, the metal film 304 is deposited conformally in the at least one feature on the bottom 301 and on the sidewall 303. It will be recognized by one of skill in the art, that the deposition may be selective. For example, in one or more unillustrated embodiments, the substrate 302 may include a dielectric portion and a metal portion, and the metal film 304 may deposit selectively on the dielectric portion and not on the metal portion. In other embodiments, the metal film 304 may deposit selectively on the metal portion of the substrate 302 and not on the dielectric portion.

One or more embodiments of the disclosure are directed to methods for bottom-up gapfill of a feature. As illustrated in FIGS. 4A to 4B, a bottom-up gapfill process fills the feature 406 from the bottom versus a conformal process which fills the feature from the bottom 401 and sides 403. As illustrated in FIGS. 4A to 4B, which illustrate cross-sectional views of a substrate 402 being processed according to the method 100, a metal film 404 is deposited as a gapfill on a substrate 402 having at least one feature 406 including a bottom 401 and at least on sidewall surface 403. In one or more embodiments, the metal film 404 is deposited in a bottom-up matter in the at least one feature 406 to fill the at least one feature 406 with the metal film 404. In one or more embodiments, the at least one feature 406 may include a liner 408 and the metal film 404 may form on the liner 408. In one or more embodiments, the feature 406 has a first material at the bottom 401 (e.g., a nitride) and a second material (e.g., an oxide) at the sidewalls 403. The metal film 404 deposits selectively on the first material relative to the second material so that the metal film 404 fills the feature in a bottom-up manner.

According to one or more embodiments, the substrate is subjected to processing prior to and/or after forming the metal film. This processing can be performed in the same chamber or in one or more separate processing chambers. In one or more embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. The exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In one or more embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrate are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In one or more embodiments, the substrate support includes a heater/cooler which can be controlled to change the substrate temperature conductively. In one or more embodiments, the gases (either reactive gases or inert gases) being employed are heated or cooled to locally change the substrate temperature. In one or more embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a film on a semiconductor substrate, the method comprising:
sequentially exposing a substrate surface to a metal halide precursor comprising a first metal and diethyl zinc to form a metal film comprising the first metal and zinc,
wherein the metal film has a carbon concentration of less than or equal to 5 atomic percent.

2. The method of claim 1, wherein the substrate surface is not exposed to a strong reductant to form the metal film.

3. The method of claim 1, wherein the first metal is selected from one or more of tantalum (Ta), aluminum (Al), niobium (Nb), titanium (Ti), zirconium (Zr), hafnium (Hf), tungsten (W), and molybdenum (Mo).

4. The method of claim 1, wherein the metal film has a metal concentration of greater than or equal to about 95 atomic percent.

5. The method of claim 7, wherein the metal halide precursor is selected from the group consisting of tantalum chloride, aluminum chloride, niobium chloride, titanium chloride, zirconium chloride, hafnium chloride, tungsten chloride, molybdenum chloride, tantalum bromide, aluminum bromide, niobium bromide titanium bromide, zirconium bromide, hafnium bromide, tungsten bromide, molybdenum bromide, tantalum fluoride, aluminum fluoride, niobium fluoride, titanium fluoride, zirconium fluoride, hafnium fluoride, tungsten fluoride, molybdenum fluoride, tantalum iodide, aluminum iodide, niobium iodide, titanium iodide, zirconium iodide, hafnium iodide, tungsten iodide, and molybdenum iodide.

6. The method of claim 1, further comprising exposing the substrate surface to an additional reactant to form the metal film.

7. The method of claim 6, wherein the additional reactant comprises one or more of an amine, a silane, or a metal hydride comprising the first metal or zinc.

8. A method of depositing a film on a semiconductor substrate, the method comprising:
sequentially exposing at least a portion of a substrate surface to a metal halide precursor and a diethyl zinc to form a metal film without exposing the substrate surface to a strong reductant.

9. The method of claim 8, wherein the metal film comprises greater than or equal to about 95 atomic percent metal.

10. The method of claim 8, wherein a carbon content of the metal film is less than or equal to about 5 atomic percent.

11. The method of claim 8, wherein the metal is selected from one or more of tantalum (Ta), aluminum (Al), niobium (Nb), titanium (Ti), zirconium (Zr), hafnium (Hf), tungsten (W), and molybdenum (Mo).

12. The method of claim 8, further comprising exposing the substrate surface to an additional reactant to form the metallic film.

13. The method of claim 12, wherein the additional reactant comprises one or more of an amine, a silane, or a metal hydride comprising the metal.

14. The method of claim 8, wherein the metal halide precursor is selected from the group consisting of tantalum chloride, aluminum chloride, niobium chloride, titanium chloride, zirconium chloride, hafnium chloride, tungsten chloride, molybdenum chloride, tantalum bromide, aluminum bromide, niobium bromide titanium bromide, zirconium bromide, hafnium bromide, tungsten bromide, molybdenum bromide, tantalum fluoride, aluminum fluoride, niobium fluoride, titanium fluoride, zirconium fluoride, hafnium fluoride, tungsten fluoride, molybdenum fluoride, tantalum iodide, aluminum iodide, niobium iodide, titanium iodide, zirconium iodide, hafnium iodide, tungsten iodide, and molybdenum iodide.

15. The method of claim 8, wherein the metal halide precursor comprises TaCl₃.

16. A method of depositing a metal alloy film on a semiconductor substrate, the method comprising:
exposing a substrate surface to a metal halide precursor comprising a first metal to form a reactive species on the substrate surface; and
exposing the substrate surface to diethyl zinc to react with the reactive species to form the metal alloy film comprising the first metal and zinc,
wherein the metal alloy film has a carbon concentration of less than or equal to 5 atomic percent.

17. The method of claim 16, wherein the metal alloy film is formed without using a strong reductant.

18. The method of claim 16, wherein the metal alloy film contains in a range of from 0.5 atomic % zinc to 20 atomic % zinc.

19. The method of claim 16, wherein the metal halide precursor is selected from the group consisting of tantalum chloride, aluminum chloride, niobium chloride, titanium chloride, zirconium chloride, hafnium chloride, tungsten chloride, molybdenum chloride, tantalum bromide, aluminum bromide, niobium bromide titanium bromide, zirconium bromide, hafnium bromide, tungsten bromide, molybdenum bromide, tantalum fluoride, aluminum fluoride, niobium fluoride, titanium fluoride, zirconium fluoride, hafnium fluoride, tungsten fluoride, molybdenum fluoride, tantalum iodide, aluminum iodide, niobium iodide, titanium iodide, zirconium iodide, hafnium iodide, tungsten iodide, and molybdenum iodide.

20. The method of claim 16, further exposing the substrate surface to an additional reactant to form the metal alloy film, the additional reactant comprising one or more of an amine, a silane, or a metal hydride comprising the first metal or zinc.
